(19) United States
(12) Patent Application Publication
(10) Pub. No.: US 2014/0241335 A1
(43) Pub. Date: Aug. 28, 2014

(54) PHASE-LOCKED LOOP USING DUAL LOOP MODE TO ACHIEVE FAST RESETTLING

(71) Applicant: QUALCOMM INCORPORATED, San Diego, CA (US)

(72) Inventors: Xinhua Chen, San Diego, CA (US); Yiwu Tang, San Diego, CA (US)

(73) Assignee: QUALCOMM INCORPORATED, San Diego, CA (US)

(21) Appl. No.: 13/780,968

(22) Filed: Feb. 28, 2013

(51) Int. Cl. H03L 7/06

(52) U.S. Cl. CPC H03L 7/06
USPC 370/342; 327/156; 327/157

(57) ABSTRACT

A PLL operates in a first low bandwidth mode using a first control loop and in a second high bandwidth mode using a second control loop. The PLL includes a VCO that generates an output signal at a desired frequency used by a transmitter. When the transmitter switches from a High Power mode (HP TX) to a Low Power mode (LP TX), the PLL is perturbed (VCO no longer generates the desired frequency) and must resettle within an allocated time. In one example, the VCO frequency is 3.96 GHz and the settling time requirement is 25 microseconds. Upon switching from HP TX to LP TX, the PLL is switched to the second high bandwidth mode 15 microseconds and is then switched back to the first low bandwidth mode. The PLL resettles to within 1 ppm of the initial VCO frequency of 3.96 GHz within the allocated 25 microseconds.

### BACKGROUND INFORMATION

1. Technical Field

The disclosed embodiments relate generally to wireless communication systems, and more particularly, to Phase Locked Loops (PLLs) in radio front end circuitry for up-converting and down-converting transmission signals.

2. Background Information

FIG. 1 (Prior Art) is a diagram of one type of conventional Phase-Locked Loop (PLL) 10. PLL 10 includes a Phase-Frequency Detector (PFD) 11, a charge pump 12, a loop filter 13, a Voltage Controlled Oscillator (VCO) 14 and a frequency divider 15. A PLL output signal PLL_OUT 16 is supplied to a VCO buffer 17. VCO buffer 17 supplies a VCO buffer output signal 18 to a Local Oscillator (LO) buffer 19. LO buffer 19 generates output signal 20 that in turn drives a transmitter 21 of a mobile handset (not shown). Whether the transmitter 21 operates in a high power mode or in a low power mode is determined by a digital control signal HP 27. In the example of FIG. 1, the mobile handset engages in Global System for Mobile (GSM) communications.

At times during operation of the mobile handset, the PLL 10 may be perturbed. The transmitter 21 is disabled and the PLL 10 is allocated an amount of time to resettle. After the PLL 10 has resettled, the transmitter 21 is enabled for transmission and wireless communication can resumed. The amount of time allocated for PLL resettling is referred to as a settling time requirement. The settling time requirement varies depending on the type of communication and the protocols supported.

In the present specific example involving GSM communications, the settling time requirement is one millisecond. When PLL 10 is perturbed, the PLL 10 switches from a low bandwidth mode (100 kHz) into a high bandwidth mode (1 MHz). The PLL 10 operates in the high bandwidth mode for a first five-hundred microsecond time period. The PLL 10 then switches back to operate in its normal low bandwidth mode. After switching back to the low bandwidth mode, the PLL 10 resettles within a second five-hundred microsecond time period. A digital logic control signal HB 22 controls whether the PLL 10 is operating in the low bandwidth mode or in the high bandwidth mode. The digital logic control signal HB 22 is supplied to charge pump 12 and to loop filter 13 via conductor 23.

FIG. 2 (Prior Art) is an idealized waveform diagram that illustrates operation of the conventional PLL 10 of FIG. 1. At time T0, the PLL 10 is perturbed. The waveform of the VCO frequency at the top of FIG. 2 shows how the PLL 10 is perturbed at time T0. Control signal HB 22 switches from a digital logic low level to a digital logic high level. This causes PLL 10 to switch operation into the high bandwidth mode. Asserting control signal HB 22 controls switches in the charge pump 12 so that the charge pump output current ICP 24 is increased by a factor of between eight and sixteen times the normal charge pump current generated in the low bandwidth mode. Asserting control signal HB 22 also controls a switch 25 in the loop filter 13 to open-circuit a resistor R0 26. The increase in charge pump output current ICP 24 and the disengaging of resistor R0 26 causes PLL 10 to exhibit an increased loop bandwidth. The PLL 10 is operated in this high bandwidth mode for the first five-hundred microsecond time period.

At time T1 , at the beginning of the second five-hundred microsecond time period, the control signal HB 22 is switched back to the digital logic low level. Deasserting control signal HB 22 at time T1 causes the charge pump 12 to decrease the charge pump output current ICP 24 to the normal charge pump current level. Deasserting control signal HB 22 also controls switch 25 in loop filter 13 to couple resistor R0 26 into the loop filter. The decrease in charge pump output current ICP 24 and the coupling of resistor R0 into the loop filter causes the PLL 10 to exhibit a decreased loop bandwidth. The waveform of the VCO frequency at the top of FIG. 2 shows how the PLL has resettled by time T2 so that the frequency of the VCO output signal is within one part per million of the frequency the VCO output signal initially had at time T0. Although the PLL 10 has resettled within the allotted one millisecond settling time requirement, a low-power PLL that achieves a faster resettling time is desirable.

### SUMMARY

A Phase-Locked Loop (PLL) of a local oscillator is operable in two modes, a first low bandwidth mode and a second high bandwidth mode. In the first low bandwidth mode, the PLL uses a first control loop that includes a first charge pump and a first loop filter, and has a bandwidth BW1. The first control loop drives the Voltage Controlled Oscillator (VCO) of the PLL. In the second high bandwidth mode, the PLL uses a second control loop that includes a second charge pump and a second loop filter, and has a bandwidth BW2 that is at least twice BW1. The second control loop drives the VCO.

In one embodiment, the local oscillator is part of a transmitter of a mobile communication device. The VCO of the PLL outputs a VCO output signal (VO) that in turn is used to generate a local oscillator output signal (LO). The local oscillator output signal LO is output from the local oscillator and is supplied to a mixer of the transmitter. The transmitter is operable in a high power (HP) TX mode and in a Low Power (LP) TX mode. The HP TX mode is high current consumption mode, whereas the LP TX mode is a low current consumption mode. In certain circumstances it is desirable to switch the transmitter from operating in the HP TX mode to operating in the LP TX mode in order to reduce power consumption. When the transmitter switches from the HP TX mode to LP TX mode, however, the PLL may be perturbed, for example due to a change in loading on the VCO. The PLL may, for example, be perturbed due to a VCO buffer and/or an LO buffer switching from a high power mode to a low power mode coincidental with the transmitter switching from the HP TX mode to the LP TX mode. By operating the PLL in the second high bandwidth mode for a predetermined and controlled High Bandwidth Time Period (HBWTP) after the transmitter switches into the LP TX mode, the PLL settles within a reduced settling time (for example, twenty-five microseconds).

In one specific example, the mobile communication device engages in a

Wideband Code Division Multiple Access (W-CDMA) communication that requires the PLL to have a settling time of twenty-five microseconds after the PLL is perturbed. Initially, the transmitter operates in the HP TX mode and the PLL operates in the first low bandwidth mode. Accordingly, the first control loop that has a loop bandwidth (BW1) of 100 KHz is used to drive the VCO. The VCO output signal has a frequency F_{VCO}_{_{—}}_{BEGIN} of 3.96 GHz. The PLL is said to be in “normal operation”.

The transmitter is then made to switch from operating in the HP TX mode to operating in the LP TX mode. In response to the transmitter switching power modes, a mode control circuit in the PLL controls the PLL to switch from operating in the first low bandwidth mode to operating in the second high bandwidth mode. In the second high bandwidth mode, the second control loop (that has a loop bandwidth (BW2) of 1 MHz, or ten times BW1) drives the VCO. The PLL operates in this second high bandwidth mode for the HBWTP time period. In this example, HBWTP is fifteen microseconds. By the end of this HBWTP time period, the VCO output frequency F_{VCO}_{_{—}}_{END} has settled to be within one part-per million (ppm) of the initial VCO frequency F_{VCO}_{_{—}}_{BEGIN} (3.96 GHz). Accordingly, the frequency F_{VCO}_{_{—}}_{END} is substantially identical to the frequency F_{VCO}_{_{—}}_{BEGIN}.

After operating in the second high bandwidth mode for this HBWTP time period, the mode control circuit of the PLL controls the PLL to switch from operating in the second high bandwidth mode to operating in the first low bandwidth mode. Within ten microseconds, the VCO output frequency F_{VCO} settles to be within one ppm of the initial VCO frequency F_{VCO}_{_{—}}_{BEGIN} (3.96 GHz).

After the twenty-five microsecond settling time, the mode control circuit of the PLL continues to keep the PLL operating in the first low bandwidth mode. The PLL is said to resume “normal operation”. The transmitter, however, is now operating in its LP TX mode.

The foregoing is a summary and thus contains, by necessity, simplifications, generalizations and omissions of detail; consequently, those skilled in the art will appreciate that the summary is illustrative only and does not purport to be limiting in any way. Other aspects, inventive features, and advantages of the devices and/or processes described herein, as defined solely by the claims, will become apparent in the non-limiting detailed description set forth herein.

### BRIEF DESCRIPTION OF THE DRAWINGS

FIG. 1 (Prior Art) is a block diagram of a conventional Phase-Locked Loop (PLL) circuit 10.

FIG. 2 (Prior Art) is a diagram of idealized waveforms illustrating operation of the conventional PLL circuit 10 of FIG. 1.

FIG. 3 is a very simplified high level block diagram of one particular type of mobile communication device 100 in accordance with one novel aspect.

FIG. 4 is a more detailed block diagram of the RF transceiver integrated circuit 103 of FIG. 3.

FIG. 5 is a diagram that shows local oscillator 120 of FIG. 4 in further detail.

FIG. 6 is a more detailed diagram of circuitry of the first control loop and circuitry of the second control loop of the PLL 137 of FIG. 5.

FIG. 7 is a circuit diagram of the VCO 152 of FIG. 5.

FIG. 8 is a diagram that shows operation of the PLL in the first low bandwidth mode.

FIG. 9 is a diagram that shows operation of the PLL in the second high bandwidth mode.

FIG. 10 is a diagram of idealized waveforms illustrating operation of the circuit of FIG. 5.

FIG. 11 is a block diagram of a novel DAC-based digital PLL 240 in accordance with another embodiment.

FIG. 12 is a flowchart of a method 300 in accordance with one novel aspect.

### DETAILED DESCRIPTION

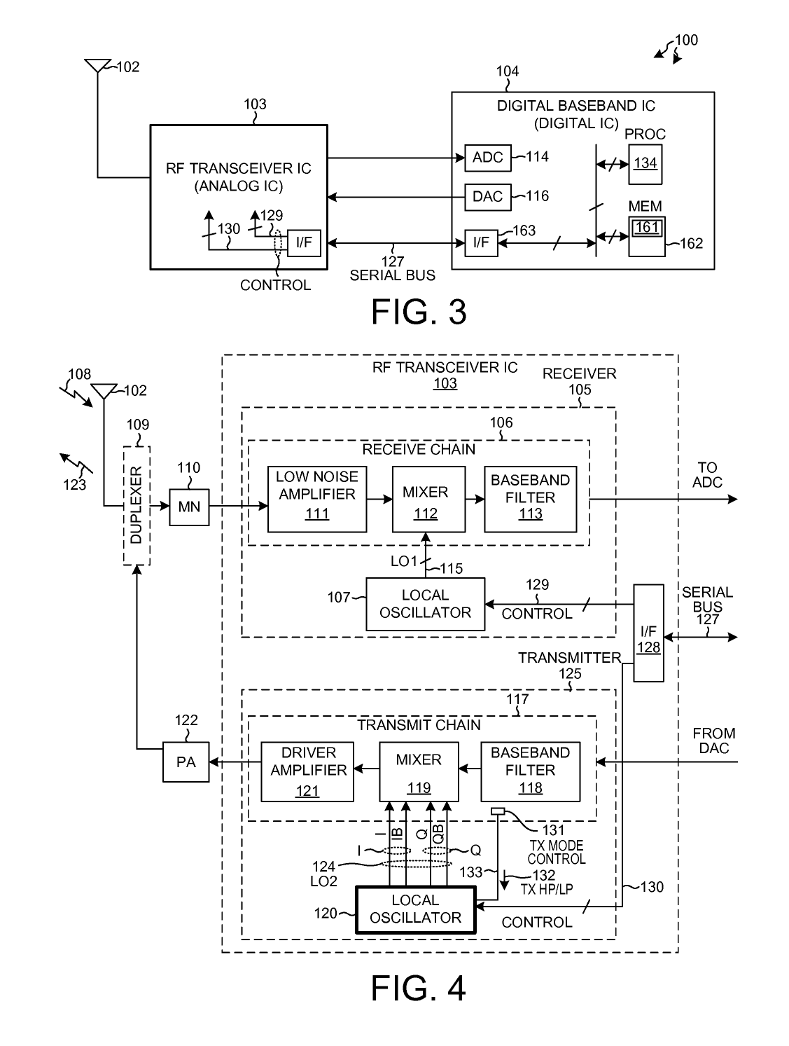

FIG. 3 is a very simplified high level block diagram of a mobile communication device 100 in accordance with one novel aspect. In this example, mobile communication device 100 is a cellular telephone. The cellular telephone includes (among several other components not illustrated) an antenna 102 and two integrated circuits 103 and 104. Integrated circuit 104 is called a “digital baseband integrated circuit.” Integrated circuit 103 is a Radio Frequency (RF) transceiver integrated circuit. RF transceiver integrated circuit 103 is called a “transceiver” because it includes a transmitter as well as a receiver.

FIG. 4 is a more detailed block diagram of the RF transceiver integrated circuit 103 of FIG. 3. A receiver 105 includes what is called a “receive chain” 106 as well as a Local Oscillator (LO) 107. When the cellular telephone 100 is receiving, a high frequency RF signal 108 is received on antenna 102. Information from signal 108 passes through duplexer 109, matching network 110, and through the receive chain 106. Signal 108 is amplified by Low Noise Amplifier (LNA) 111 and is down-converted in frequency by mixer 112. The resulting down-converted signal is filtered by baseband filter 113 and is passed to the digital baseband integrated circuit 104. An analog-to-digital converter 114 in the digital baseband integrated circuit 104 converts the signal into digital form and the resulting digital information is processed by digital circuitry in the digital baseband integrated circuit 104. The digital baseband integrated circuit 104 tunes the receiver by controlling the frequency of the Local Oscillator (LO1) signal supplied on local oscillator outputs 115 to mixer 112.

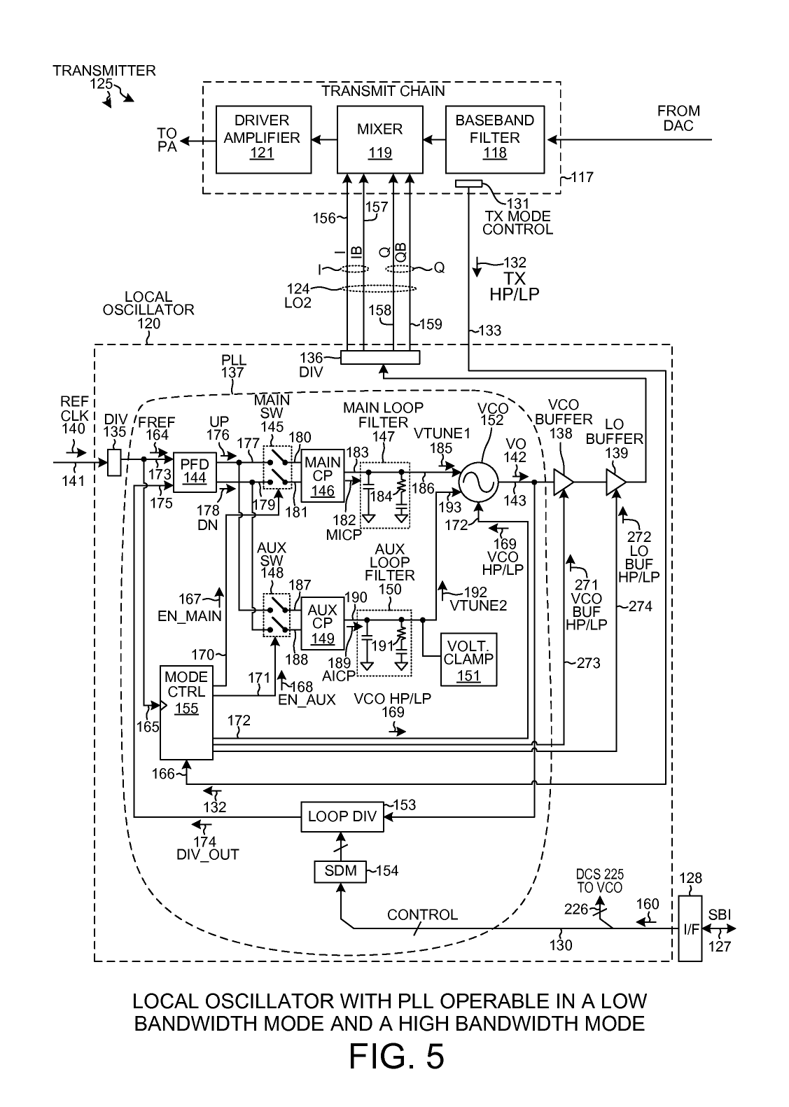

If the cellular telephone 100 is transmitting, then information to be transmitted is converted into analog form by a Digital-to-Analog Converter (DAC) 116 in the digital baseband integrated circuit 104 and is supplied to a “transmit chain” 117 in the RF transceiver integrated circuit 103. Baseband filter 118 then filters out noise due to the digital-to-analog conversion process. Mixer block 119 under control of local oscillator 120 then up-converts the signal into a high frequency signal. Driver amplifier 121 and an external power amplifier 122 amplify the high frequency signal to drive antenna 102 so that a high frequency RF signal 123 is transmitted from antenna 102. The digital baseband integrated circuit 104 controls the transmitter 125 by controlling the frequency of a Local Oscillator (LO2) signal 124 to mixer 119. Transmitter 125 includes the transmit chain 117 and the local oscillator 120. Local oscillator signal LO2 124 includes a differential In-phase (I) signal and a differential Quadrature (Q) signal that are supplied via conductors 156-159 (see also FIG. 5) to mixer 119. Digital baseband integrated circuit 104 controls the local oscillators 107 and 120 by sending appropriate control information across digital bus 127, through bus interface 128, and control lines 129 and 130.

A transmit mode control circuit 131 generates a digital logic control signal TX HP/LP 132. The TX HP/LP signal 132 is indicative of whether the cellular telephone 100 is operating in a High Power (HP) mode or in a Low Power (LP) mode. The HP mode is also referred to as a high current consumption mode, and the LP mode is also referred to as a low current consumption mode. The transmit mode control circuit 131 supplies the digital logic control signal TX HP/LP 132 to the local oscillator 120 via conductor 133. In operation, transmitter 125 may operate in the HP TX mode. In the HP TX mode, the transmit mode control circuit 131 asserts the control signal TX HP/LP 132 and supplies signal TX HP/LP 132 to local oscillator 120 via conductor 133. While transmitter 125 is transmitting in the HP TX mode, processor 134 may determine that transmitter 125 should switch from transmitting in the HP mode to transmitting in the LP TX mode to reduce power consumption. If processor 134 decides to switch the transmitter 125 to the LP TX mode, then processor 134 controls circuitry within the transmit chain 117 to operate in the LP TX mode. Upon transitioning from the HP TX mode to the LP TX mode, the transmit mode control circuit 131 deasserts the control signal TX HP/LP 132 and supplies signal TX HP/LP 132 to local oscillator 120 via conductor 133.

FIG. 5 is a more detailed diagram of local oscillator 120 of the transmitter 125 in the RF transceiver integrated circuit 103 of FIG. 4. Local oscillator 120 includes dividers 135 and 136, a Phase-Locked Loop (PLL) 137, a Voltage Controlled Oscillator (VCO) buffer 138 and a Local Oscillator (LO) buffer 139. PLL 137 receives an externally generated reference signal REF CLK 140 on conductor 141 (for example, a 19.2 MHz signal generated by an external crystal oscillator) and generates therefrom a differential PLL output signal VO 142 on conductor 143. The label “VO” used here indicates that the VO signal is the VCO output signal. The PLL 137 in this example includes a Phase-Frequency Detector (PFD) 144, a main switch 145, a main charge pump 146, a main loop filter 147, an auxiliary switch 148, an auxiliary charge pump 149, an auxiliary loop filter 150, a voltage clamp 151, a Voltage Controlled Oscillator (VCO) 152, a loop divider 153, a Sigma-Delta Modulator (SDM) 154 and a mode control circuit 155. The VO signal 142 output by the VCO 152 is divided down in frequency by divider 136 to generate local oscillator signal LO2 124. The local oscillator signal LO2 124 includes a differential In-phase (I) signal and a differential Quadrature (Q) signal and is supplied to the mixer 119 of the transmit chain 117 via conductors 156-159. A multi-bit digital control signal 160 is determined by the processor 134 (see FIG. 3) in digital baseband integrated circuit 104 by the execution of a set of processor-executable instructions 161 stored in a processor-readable medium 162. After the multi-bit digital control signal 160 is determined, it is communicated through serial bus interface 163, serial bus 127, serial bus interface 128, and conductors 130 to local oscillator 120.

Mode control circuit 155 controls whether the PLL 137 operates: 1) in a first low bandwidth mode using a first control loop, or 2) in a second high bandwidth mode using a second control loop. The mode control circuit 155 receives the divided down reference clock signal FREF 164 onto input lead 165 and the control signal TX HP/LP 132 onto input lead 166, and generates control signal EN_MAIN 167, control signal EN_AUX 168, control signal VCO HP/LP 169, control signal VCO BUF HP/LP 271 and control signal LO BUF HP/LP 272. The control signal EN_MAIN 167 is supplied to the main switch 145 via conductor 170. The control signal EN_AUX 168 is supplied to the auxiliary switch 148 via conductor 171. The control signal VCO HP/LP 169 is supplied to the VCO 152 via a mode control input lead 172. The control signal VCO BUF HP/LP 271 is supplied to the VCO buffer 138 via conductor 273. The control signal LO BUF HP/LP 272 is supplied to the LO buffer 139 via conductor 274. The PH) 144 receives the clock signal FREF 164 onto input lead 173 and receives a divided-down single-bit feedback signal DIV_OUT 174 onto input lead 175. From these signals, PFD 144 generates and supplies an up charge pump control signal UP 176 onto output lead 177 and a down charge pump control signal DN 178 onto output lead 179. The signals UP 176 and DN 178 are digital signals. Mode control circuit 155 determines whether the digital signals UP 176 and DN 178 propagate through the first control loop (in the first low bandwidth mode) or through the second control loop (in the second high bandwidth mode), as explained below.

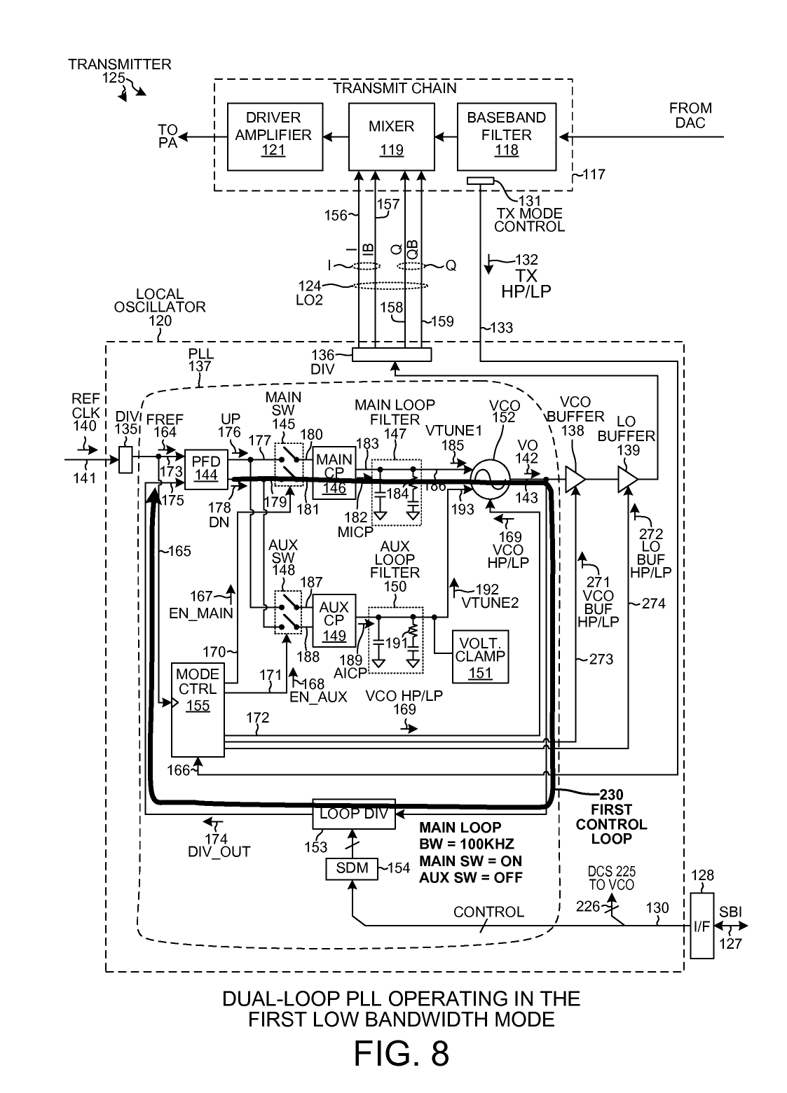

If the mode control circuit 155 determines the PLL 137 should operate in the first low bandwidth mode, then mode control circuit 155 asserts the control signal EN_MAIN 167 to a digital logic high level and deasserts the control signal EN_AUX 168 to a digital logic low level. This causes the up charge pump control signal UP 176 and the down charge pump control signal DN 178 to be supplied to the main charge pump146 via conductors 180 and 181, respectively. The main charge pump 146 receives the charge pump control signals UP 176 and DN 178 and generates a charge pump output current pulse train signal MICP 182 supplied to main loop filter 147 via conductor 183. In this example, the main loop filter 147 is a low-pass filter and includes a resistor 184. After low-pass filtering of the pulse train signal MICP 182, the main loop filter 147 supplies a tuning signal VTUNE1 185 onto VCO 152 via tuning control input lead 186. The signal VTUNE1 185 controls the VCO 152 to output signal VO 142 onto conductor 143. In this example, signal VTUNE1 185 has a desired operating point of 1.0 volts +/−300.0 millivolts. Accordingly, in the first low bandwidth mode, the PLL 137 uses the main switch 145, the main charge pump 146 and the main loop filter 147 which are parts of the first control loop. A signal propagation path through the first control loop is identified by a bold line and arrow 230 in FIG. 8.

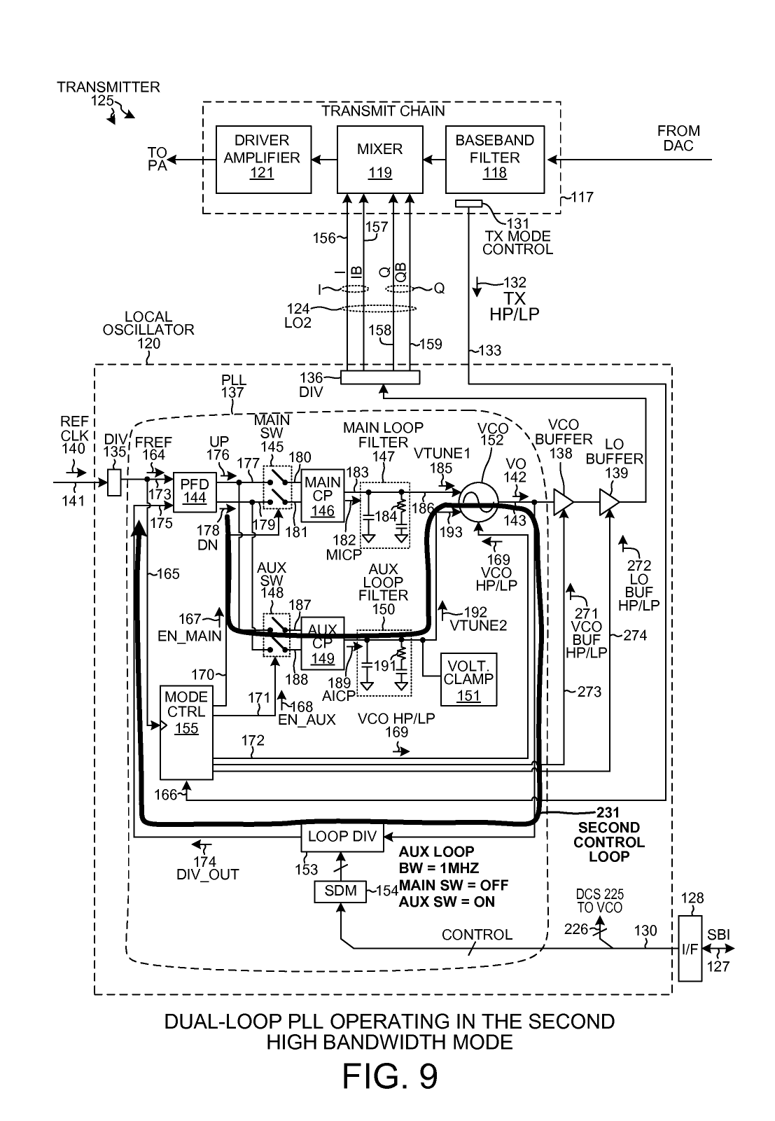

If, on the other hand, the mode control circuit 155 determines the PLL 137 should operate in the second high bandwidth mode, then mode control circuit 155 deasserts the control signal EN_MAIN 167 to a digital logic low level and asserts the control signal EN_AUX 168 to a digital logic high level. This causes the up charge pump control signal UP 176 and a down charge pump control signal DN 178 to be supplied to the auxiliary charge pump 149 via conductors 187 and 188, respectively. The auxiliary charge pump 149 receives the charge pump control signals UP 176 and DN 178 and generates a charge pump output current pulse train signal AICP 189 supplied to auxiliary loop filter 150 via conductor 190. In this example, the auxiliary loop filter 150 is a low-pass filter and includes resistor 191. Resistor 191 has a lower resistance than does resistor 184 of the main loop filter 147. After low-pass filtering of the pulse train signal AICP 189, the auxiliary loop filter 150 supplies a tuning signal VTUNE2 192 onto VCO 152 via tuning control input lead 193. The signal VTUNE2 192 controls the VCO 152 to output signal VO 142 onto conductor 143. Accordingly, in the second high bandwidth mode, the PLL 137 uses the auxiliary switch 148, the auxiliary charge pump 149 and the auxiliary loop filter 150 which are parts of the second control loop. A signal propagation path through the second control loop is identified by a bold line and arrow 231 in FIG. 9.

Processor 134 in the digital baseband IC 104 may determine that transmitter 125 is to switch from transmitting in the HP TX mode to transmitting in the LP TX mode in order to decrease power consumption. In one example transmit operation using the PLL 137 of FIG. 5, the PLL 137 operates in the first low bandwidth mode and the VCO 152 outputs the VCO output signal VO 142 having a frequency of 3.96 GHz. The signal VO 142 is used to generate the signal LO2 124 that is supplied to the transmit chain 117 of the transmitter 125 while the transmitter 125 is operating in the HP TX mode. Upon switching the transmitter 125 from operating in HP TX mode to operating in the LP TX mode, PLL 137 may be perturbed such that the signal VO 142 is no longer at the desired frequency of 3.96 GHz. PLL 137 may be perturbed due to the VCO 152 being switched to a lower power mode, due to VCO buffer 138 being switched to a lower power mode, and/or due to LO buffer 139 being switched to a lower power mode, where one or more of these switches occurs concurrently with the transmitter switching from the HP TX mode to the LP TX mode.

In order to resettle the PLL 137, the transmit mode control circuit 131 controls

PLL 137 to switch into the second high bandwidth mode. The PLL 137 operates in the second high bandwidth mode using the second control loop for a period of time referred to here as a “High Bandwidth Time Period” (HBWTP). In this example, HBWTP is fifteen microseconds. By the ending of this HBWTP time period, the VCO output signal VO 142 has settled to a frequency substantially identical to (within one ppm of) the initial frequency of 3.96 GHz. After the HBWTP time period, the transmit mode control circuit 131 controls the PLL 137 to resume operation in the first low bandwidth mode. Within ten microseconds of switching the PLL 137 to operate in the first low bandwidth mode, the PLL 137 has resettled so that its VCO output frequency is within 1 ppm of the initial VCO output frequency of 3.96 GHz. Thereafter, in what is referred to as “normal operation”, the PLL 137 remains operating in the first low bandwidth mode. By operating the PLL 137 in this fashion, the PLL 137 is seen to resettle within twenty-five microseconds of the transmitter 125 switching from the HP TX mode to the LP TX mode.

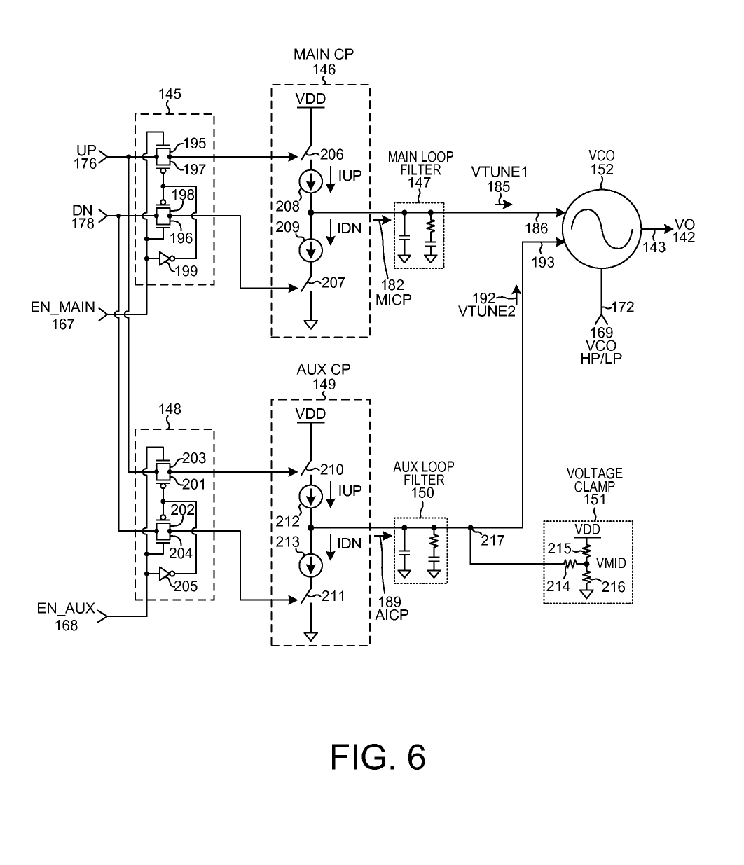

FIG. 6 is a more detailed diagram of circuitry that is part of the first control loop (main switch 145, main charge pump 146 and main loop filter 147) and circuitry that is part of the second control loop (auxiliary switch 148, auxiliary charge pump 149, auxiliary loop filter 150 and voltage clamp 151). Main switch 145 includes N-type Field Effect Transistors (FETs) 195 and 196, P-type FETs 197 and 198, and a NOT gate 199. Auxiliary switch 148 includes P-type FETs 201 and 202, N-type FETs 203 and 204, and a NOT gate 205. FETs 195, 197, 201 and 203 form a first 1:2 analog transmission gate demultiplexer. FETs 196, 198, 202 and 204 form a second 1:2 analog transmission gate demultiplexer. These demultiplexers are switched on the falling edge of the clock signal FREF 164. When PLL 137 is operating in the first low bandwidth mode, the mode control circuit 155 controls EN_MAIN 167 to a digital logic high level and controls EN_AUX 168 to a digital logic low level, thereby causing charge pump control signals UP 176 and DN 178 to be supplied to the main charge pump 146. When PLL 137 is operating in the second high bandwidth mode, the mode control circuit 155 controls EN_MAIN 167 to a digital logic low level and controls EN_AUX 168 to a digital logic high level, thereby causing charge pump control signals UP 176 and DN 178 to be supplied to the auxiliary charge pump 149.

The diagrams of the main charge pump 146 and the auxiliary charge pump 149 in FIG. 6 are simplifications. In the simplification, the main charge pump 146 includes switches 206 and 207, and current sources 208 and 209. The upper switch 206 controls the flow of IUP current, and the lower switch 207 controls the flow of IDN current. The switches 206 and 207 are controlled to switch on and off by the pump control signals UP 176 and DN 178 when the PLL 137 is in the first mode thereby generating signal MICP 182. The auxiliary charge pump 149 includes switches 210 and 211 and current sources 212 and 213. The upper switch 210 controls the flow of IUP current, and the lower switch 211 controls the flow of IDN current. The switches 210 and 211 are controlled to switch on and off by the pump control signals UP 176 and DN 178 when the PLL 137 is in the second mode thereby generating signal AICP 189.

Voltage clamp 151 includes resistors 214, 215 and 216. VDD is approximately 2.0 volts. Voltage clamp 151 clamps the voltage on the VTUNE2 node 217 to a pre-determined mid-range voltage VMID when the PLL is operating in the first low bandwidth mode. Clamping the voltage on this node 217 to a mid-range voltage prevents the VTUNE2 node 217 from drifting to VDD or to GND due to leakage current from the main charge pump 146 and VCO 152. In the first low bandwidth mode, the signal VTUNE1 185 is to control VCO 152.

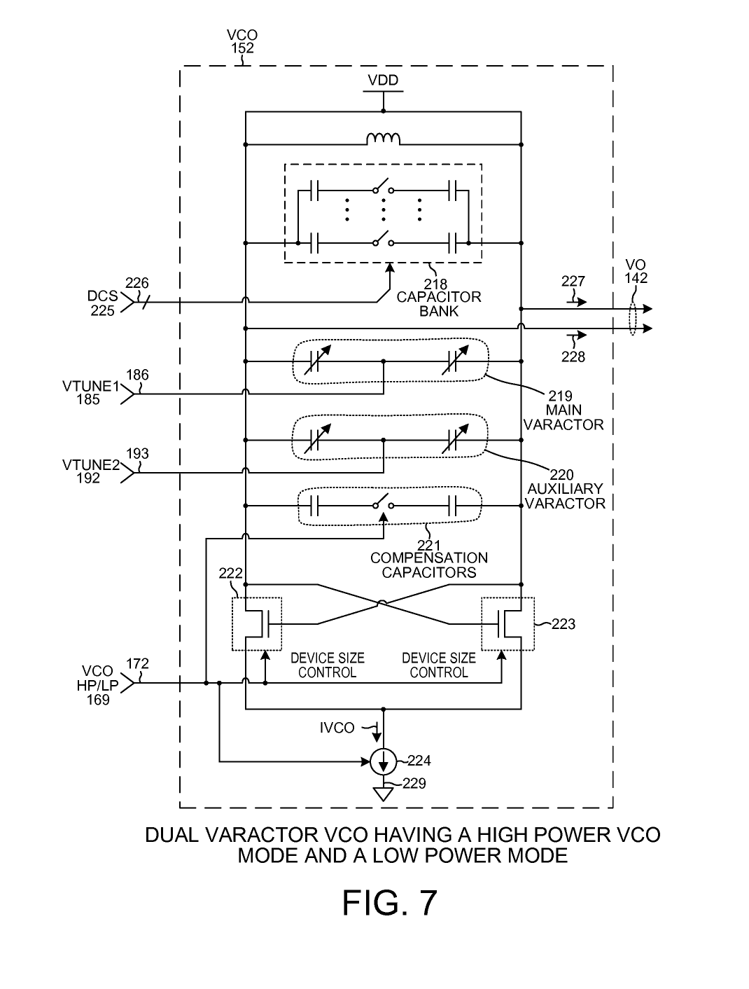

FIG. 7 is a circuit diagram of VCO 152 of FIG. 5 that has two fine tune control input leads 186 and 193. VCO 152 includes a capacitor bank 218, a main varactor 219, an auxiliary varactor 220, compensation capacitors 221, transistor circuitry 222 and 223 and a current source 224. The VCO 152 receives a coarse tune Digital Control Signal (DCS) 225 onto conductors 226, the fine tune signal VTUNE1 185 onto tuning control input lead 186, the fine tune signal VTUNE2 192 onto tuning control input lead 193, and the power control signal VCO HP/LP 169 onto mode control input lead 172. The main varactor 219 is controlled by VTUNE1 185, and the auxiliary varactor 220 is controlled by VTUNE2 192. VCO 152 outputs VO signal 142 comprising RF signals 227 and 228. VTUNE1 185 drives VCO 152 when the PLL 137 is operating in the first low bandwidth mode, whereas VTUNE2 192 drives VCO 152 when the PLL 137 is operating in the second high bandwidth mode.

In accordance with another novel aspect, VCO 152 is operable in a high current consumption mode and a low current consumption mode. The high current consumption mode is referred to as a VCO High Power (VCOHP) mode, and the low current consumption mode is referred to as a VCO Low Power (VCOLP) mode. If the transmitter 125 is operating in the HP TX mode, then the mode control circuit 155 controls the VCO 152 to operate in the VCOHP mode by asserting the control signal VCO HP/LP 169 supplied onto mode control input lead 172. To place the VCO 152 in the VCOHP mode, the compensation capacitors 221 are switched into the VCO 152. The VCO 152 is put into the higher current mode by increasing VCO current IVCO, the bias voltage of the VCO core is increased and the effective sizes of the cross-coupled N-channel transistors 222 and 223 are increased. The VCO 152 is controlled to operate in the VCOHP mode because when the transmitter 125 is operating in the HP TX mode, a lower phase error and a lower error vector magnitude (EVM) are desired. If, on the other hand, the transmitter 125 is operating in the LP TX mode, then phase error and EVM requirements are relaxed and power is saved by operating the VCO in the low power, VCOLP mode.

In one example, each of the dashed boxes 222 and 223 is actually a symbol that represents a multi-transistor circuit. Consider, for example, dashed box 222. In one example, box 222 represents two transistors that can be programmably coupled together in parallel. If the effective size of the illustrated transistor symbol 222 is to be increased in the VCOHP mode, then both the two transistors (not shown) are programmably coupled together in parallel so that the combination of the two transistors will be the same as one larger transistor. In the VCOLP mode, on the other hand, the second transistor is not coupled in parallel to the first transistor. The second transistor cannot conduct current so the combination of the two transistors (not shown) will be the same as one smaller transistor. Accordingly, what is shown in dashed box 222 in the simplified illustration of FIG. 7 is a variable-sized transistor symbol having a DEVICE SIZE CONTROL input signal.

FIG. 8 is a diagram that shows a signal propagation path 230 through the first control loop when the PLL 137 is operating in the first low bandwidth mode. Signal propagation path 230 extends through the PFD 144, the main switch 145, the main charge pump 146, the main loop filter 147, the VCO 152, and the loop divider 153. In the first low bandwidth mode, the main switch 145 is enabled and the auxiliary switch 148 is disabled, thereby causing PLL 137 to exhibit a first bandwidth BW1 of 100 KHz.

FIG. 9 is a diagram that shows a signal propagation path 231 along the second control loop when the PLL 137 is operating in the second high bandwidth mode. Signal propagation path 231 extends through the PFD 144, the auxiliary switch 148, the auxiliary charge pump 149, the auxiliary loop filter 150, the VCO 152, and the loop divider 153. In the second high bandwidth mode, the main switch 145 is disabled and the auxiliary switch 148 is enabled, thereby causing PLL 137 to exhibit a second bandwidth BW2 of 1 MHz. The second bandwidth BW2 is at least two times the first bandwidth BW1, and in this example the second bandwidth BW2 is ten times the first bandwidth BW1.

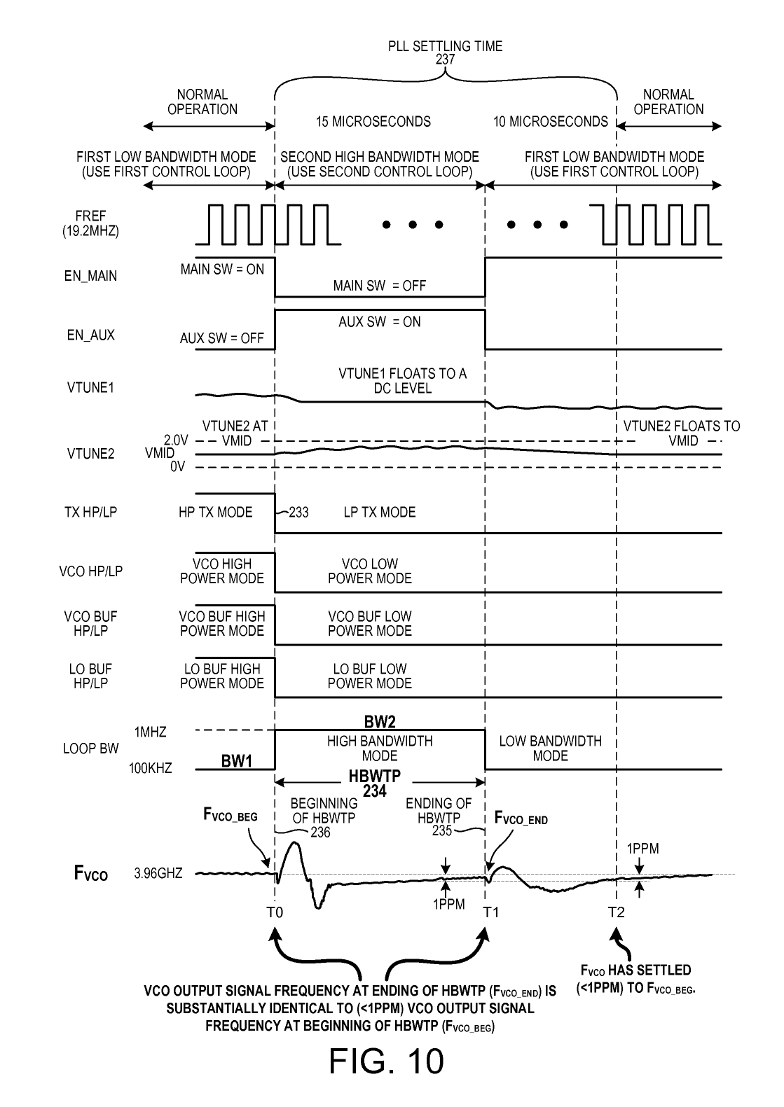

FIG. 10 is a diagram of idealized waveforms illustrating an operation of PLL circuit 137 of FIG. 5. In the example of FIG. 5, the transmitter 125 engages in a Wideband-Code Division Multiple Access (W-CDMA) standard communication having a settling time requirement of twenty-five microseconds.

Initially the transmitter 125 is transmitting in the HP TX mode. The PLL 137 is operating in the first low bandwidth mode using the first control loop having a bandwidth BW1. VCO 152 is generating the output signal VO 142 having a frequency F_{VCO}_{_{—}}_{BEG}. In this example, BW1 is 100 KHz and F_{VCO}_{_{—}}_{BEG} is approximately 3.96 GHz.

At time T0, control signal TX HP/LP transitions to a digital logic low level (233), thereby causing the transmitter 125 to stop operating in the HP TX mode and to start operating in the LP TX mode. In response to the transmitter 125 changing its operating power mode, the mode control circuit 155 deasserts EN_MAIN 167 and asserts EN_AUX 168, thereby causing PLL 137 to switch to the second high bandwidth mode. The mode control circuit controls EN_MAIN 167 and EN_AUX 168 to transition on a falling edge 232 of FREF 164. The mode control circuit 155 also deasserts control signal VCO HP/LP 168 causing the VCO 152 to switch to the low power VCOLP mode, desserts control signal VCO BUF HP/LP 271 causing the VCO buffer 138 to switch to the low power mode, and desserts control signal LO BUF HP/LP 272 causing the LO buffer 139 to switch to the low power mode.

Starting at time T0, PLL 137 operates in the second high bandwidth mode for a time period 234 referred to as the High Bandwidth Time Period (HBWTP). In the second high bandwidth mode, PLL 137 uses the second control loop having a bandwidth of BW2. In this example, HBWTP 234 is fifteen microseconds and BW2 is 1 MHz. During HBWTP 234, the signal VTUNE1 185 floats to a DC level, whereas the signal VTUNE2 192 primarily controls the VCO 152. At an ending of HBWTP 235, the VCO 152 is outputting the signal VO 142 to have a frequency F_{VCO}_{_{—}}_{END}. The frequency F_{VCO}_{_{—}}_{END} is substantially identical to the VCO output frequency F_{VCO}_{_{—}}_{BEG} at a beginning of HBWTP 236. In this example, F_{VCO}_{_{—}}_{END} is within one ppm of F_{VCO}_{_{—}}_{BEG} at the ending of HBWTP 235 just before time T1.

At time T1, after the period of time HBWTP 234 has expired, the mode control circuit 155 asserts EN MAIN 167 and deasserts EN_AUX 168. This causes PLL 137 to switch to the first low bandwidth mode. Transmitter 125, however, remains in the LP TX mode. The signal VTUNE1 185 now primarily controls the VCO 152. The signal VTUNE2 192 is set at VMID due to voltage clamp 151. The PLL 137 is perturbed again as shown in FIG. 10, but the PLL resettles within ten microseconds.

By time T2, the frequency of the VCO output signal is again within one ppm of F_{VCO}_{_{—}}_{BEG}. The PLL is said to be in “normal operation”. Reference numeral 237 identifies the twenty-five microsecond settling time period between time T0 and time T2. In this fashion, PLL 137 satisfies the W-CDMA settling time requirement of twenty-five microseconds after the transmitter 125 is switched from operating in the HP TX mode to the LP TX mode.

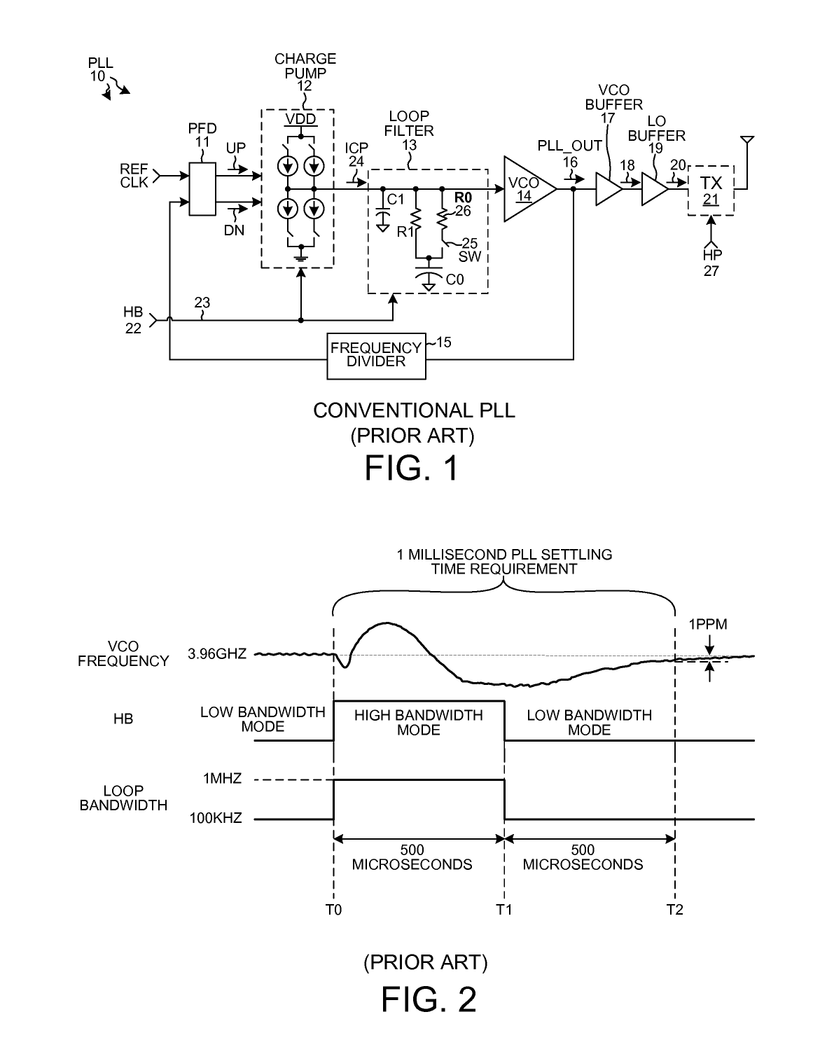

In one example, the PLL is only operated in the second high bandwidth mode during transient times when the transmitter power mode is being changed, whereas at all other times the PLL is operated in the first low bandwidth mode. The first low bandwidth mode is used throughout normal operation of the PLL. When the PLL is settling following a transmitter power change induced perturbation, the bandwidth of the PLL control loop is not changed by switching components in a loop filter nor by modifying charge pump operation as in the conventional PLL of FIG. 1, but rather the change in PLL control loop bandwidth is achieved by switching in a different change pump 149 and a different loop filter 150. The peak output current of the current pulses output by charge pump 146 is not being modified during this transient time. The peak output current of the current pulses output by charge pump 149 is not being modified during this transient time. The components of loop filter 147 are also fixed and the filter response of loop filter 147 does not change during this transient time. The components of loop filter 150 are also fixed and the filter response of loop filter 150 does not change during this transient time. Because the second control loop is not used during normal PLL operation, the second control loop can be optimized for its function in achieving fast PLL settling during the transient times (after a transmitter power change induced PLL perturbation). As compared to the conventional PLL of FIG. 1 where analog signals are switched to change circuit bandwidth, in PLL 137 digital signals UP 176 and DN 178 are digitally demultiplexed to the charge pumps to change circuit bandwidth.

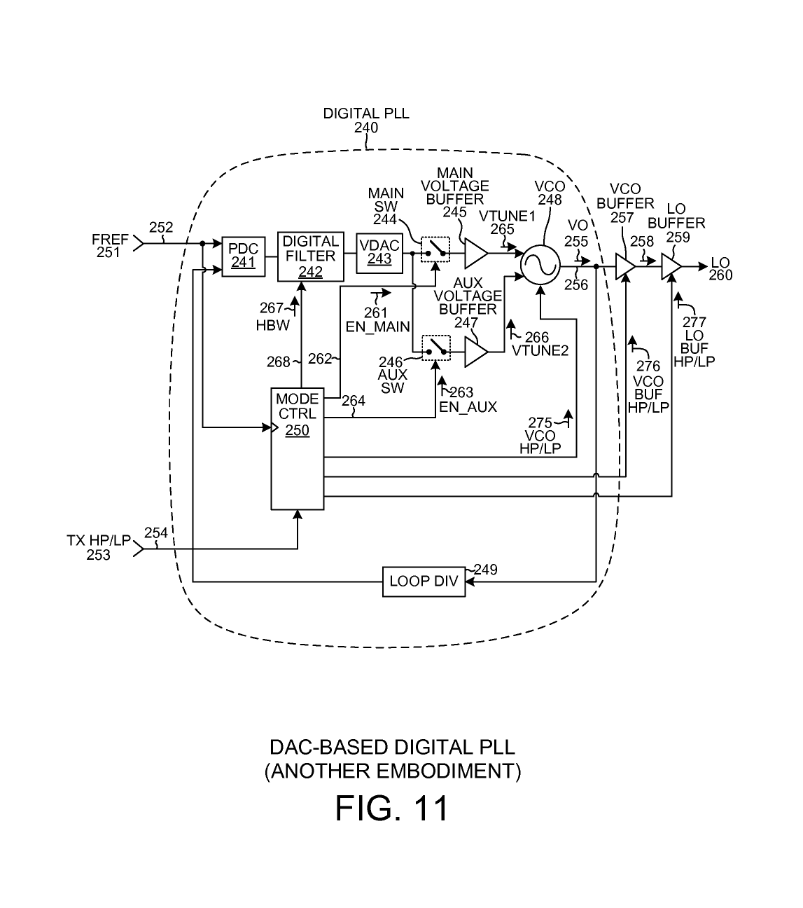

FIG. 11 is a diagram of a Digital-to-Analog-Converter (DAC)-based PLL 240 in accordance with another embodiment. DAC-based digital PLL 240 includes a Phase-to-Digital Converter (PDC) 241, a digital filter 242, a Voltage-Mode Digital-to-Analog Converter (VDAC) 243, main switch 244, main voltage buffer 245, auxiliary switch 246, auxiliary voltage buffer 247, Voltage Controlled Oscillator (VCO) 248, a loop divider 249, and a mode control circuit 250. The DAC-based digital PLL 240 is also more generally referred to as a digital PLL. Digital PLL 240 operates in a similar fashion as the PLL 137 of FIG. 5. Digital PLL 240 is operable in a first low bandwidth mode using a first control loop and is operable in a second high bandwidth mode using a second control loop. The digital PLL 240 receives a reference clock signal FREF 251 onto conductor 252 and a digital control signal TX HP/LP 253 supplied onto conductor 254, and generates output signal VO 255 supplied onto conductor 256. The digital control signal TX HP/LP 253 is used by the mode control circuit 250 to determine the mode the digital PLL 240 should operate in, and the signal TX HP/LP 253 is also used to control the operating mode of VCO 248, VCO Buffer 257 and LO buffer 259 similarly to the example of FIG. 5. The signal VO 255 is supplied onto a VCO buffer 257, and a VCO buffer output signal 258 is supplied onto a Local Oscillator (LO) buffer 259. LO buffer 259 generates output signal LO 260 used to drive the transmitter (not shown).

During normal operation of digital PLL 240 (the transmitter is operating in the

HP mode), the mode control circuit 250 enables main switch 244 by asserting control signal EN_MAIN 261 supplied onto conductor 262 and disables auxiliary switch 246 by deasserting control signal EN_AUX 263 supplied onto conductor 264. The main voltage buffer 245 supplies a tuning voltage control signal VTUNE1 265 onto a first tuning input of VCO 248. Under certain circumstances, the transmitter may switch to operate in the LP TX mode. In response to the transmitter switching to operate in the LP TX mode, the mode control circuit 250 disables main switch 244 by deasserting control signal EN_MAIN 261 and enables auxiliary switch 246 by asserting control signal EN_AUX 263. The auxiliary voltage buffer 247 supplies a tuning voltage control signal VTUNE2 266 to VCO 248.

In the second high bandwidth mode, the mode control circuit 250 controls digital filter 242 to have a wide loop bandwidth. Mode control circuit does this by supplying control signal HBW 267 onto conductor 268. The control signal HBW 267 in turn adjusts the cutoff frequency of the digital filter 242 such that in the first low bandwidth mode the digital filter 242 has a lower cutoff frequency, whereas in the second high bandwidth mode the digital filter 242 has a higher cutoff frequency. After the digital PLL 240 has resettled (frequency of output signal VO 255 is within 1 ppm of initial frequency prior to transmitter switching to LP mode), the mode control circuit 250 controls digital PLL 240 to operate in the first low bandwidth mode. In addition, the mode control circuit 250 deasserts control signal VCO HP/LP 275 causing the VCO 248 to switch to the low power VCOLP mode, desserts control signal VCO BUF HP/LP 276 causing the VCO buffer 257 to switch to the low power mode, and desserts control signal LO BUF HP/LP 277 causing the LO buffer 259 to switch to the low power mode. In this example, the output signal VO 255 has an initial frequency of 3.96 GHz and the digital PLL 240 resettles in less than twenty microseconds after the transmitter has switched to the LP TX mode.

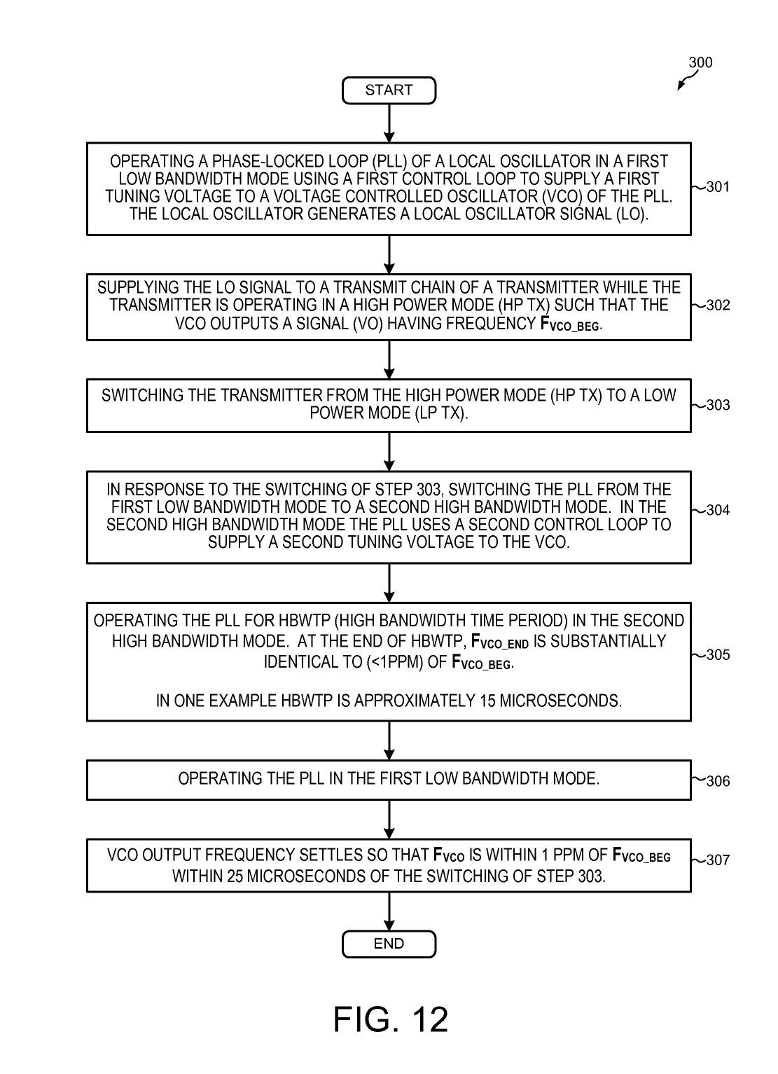

FIG. 12 is a flowchart of a method 300 in accordance with one novel aspect. In a first step (step 301), a Phase-Locked Loop (PLL) of a local oscillator operates in a first low bandwidth mode using a first control loop. The first control loop is used to supply a first tuning voltage to a Voltage Controlled Oscillator (VCO) of the PLL. The local oscillator generates a local oscillator signal (LO). For example, in the local oscillator 120 of FIG. 8, the PLL 137 operates in the first low bandwidth mode using the main charge pump 146 and the main loop filter 147. The first control loop has a bandwidth BW1 of 100 KHz and supplies tuning voltage control signal VTUNE1 185 to VCO 152.

In a second step (step 302), the local oscillator signal LO is supplied to a transmit chain of a transmitter while the transmitter is operating in a High Power (HP TX) mode. In the HP TX mode, the VCO outputs a signal VO having a frequency F_{VCO}_{_{—}}_{BEG}. For example, in FIG. 8, the local oscillator 120 supplies LO2 124 onto the mixer 119 of the transmit chain 117. The transmitter 125 is operating in a HP TX mode as indicated by digital control signal TX HP/LP 132 (see waveform diagram of FIG. 10). The signal VO 142 output by VCO 152 has a frequency F_{VCO}_{_{—}}_{BEG} of 3.96 GHz.

In a third step (step 303), the transmitter switches from operating in the HP TX mode to operating in a Low Power (LP TX) mode. For example, in the waveform diagram of FIG. 10, the digital control signal TX HP/LP 132 switches at time T0 from a digital logic high level to a digital logic low level indicating that the transmitter 125 switched to operating in the LP mode. Reference numeral 233 identifies the high-to-low transition corresponding to the transmitter switching from the transmitter high power mode (HP TX) to the transmitter low power mode (LP TX).

In a fourth step (step 304), in response to the transmitter switching to the LP TX mode, the PLL is switched from operating in the first low bandwidth mode to operating in the second high bandwidth mode. In the second high bandwidth mode, the PLL uses a second control loop to supply a second tuning voltage to the VCO. For example, in the PLL 137 of FIG. 5, the mode control circuit 155 receives the digital control signal TX HP/LP 132, and in response to the digital control signal TX HP/LP 132 switching to a digital logic low level, the mode control circuit 155 controls the main switch 145 to be disabled and controls the auxiliary switch 148 to be enabled, thereby causing the PLL 137 to enter the second high bandwidth mode. In the second high bandwidth mode, the PLL 137 uses the auxiliary charge pump 149 and the auxiliary loop filter 150. The second control loop has a bandwidth BW2 of 1 MHz, and supplies a tuning voltage control signal VTUNE2 192 to VCO 152.

In a fifth step (step 305), the PLL operates in the second high bandwidth mode for a High Bandwidth Time Period (HBWTP). At the end of the HBWTP time period, the output frequency of the VCO output signal VO is F_{VCO}_{_{—}}_{END}. This frequency F_{VCO}_{_{—}}_{END} is substantially identical to the initial frequency F_{VCO}_{_{—}}_{BEG} in that it is within one part-per-million (ppm) of F_{VCO}_{_{—}}_{BEG}. For example, in the waveform diagram of FIG. 10, reference numeral 234 identifies the HBWTP during which the PLL 137 is controlled to operate in the second mode. Reference numeral 236 identifies the beginning of HBWTP. The frequency of the VCO output signal VO 142 at the beginning of HBWTP 236 is F_{VCO}_{_{—}}_{BEG}. In this example, HBWTP is a fifteen microsecond time period and F_{VCO}_{_{—}}_{BEG} is 3.96 GHz. Reference numeral 235 identifies an ending of HBWTP at time T1. The frequency of the VCO output signal VO 142 at the ending of HBWTP 235 at time T1 is F_{VCO}_{_{—}}_{END}. The frequency F_{VCO}_{_{—}}_{END} is substantially identical to (within 1 ppm of) the frequency F_{VCO}_{_{—}}_{BEG}.

In a sixth step (step 306), the PLL is switched from operating in the second high bandwidth mode to operating in the first low bandwidth mode. For example, in the waveform diagrams of FIG. 10, at the ending of HBWTP 235 at time T1, the signal EN_MAIN is asserted and the signal EN_AUX is deasserted, thereby causing the PLL 137 to start operating in the first low bandwidth mode using the first control loop having a bandwidth of 100 KHz.

In a seventh step (step 307), the VCO output frequency settles so that the VCO output frequency F_{VCO} is within one ppm of F_{VCO}_{_{—}}_{BEG} within twenty-five microseconds of the time T0 when the transmitter switched from the HP TX mode to the LP TX mode in step 303. For example, in the waveform diagrams of FIG. 10, F_{VCO} is within one ppm of F_{VCO}_{_{—}}_{BEG} (3.96 GHz) within twenty-five microseconds after the time T0 (233) when the transmitter 125 was switched from the HP TX mode to the LP TX mode. Reference numeral 237 identifies the settling time which in this example is twenty-five microseconds.

Although certain specific embodiments are described above for instructional purposes, the teachings of this patent document have general applicability and are not limited to the specific embodiments described above. For example, the PLL 137 may be a part of the local oscillator 107 of receiver 105 in which the PLL 137 is controlled in a similar fashion as in transmitter 125. If the receiver 105 switches from operating in a HP RX mode to a LP RX mode, then PLL 137 may be perturbed due to a change in loading of the VCO. In response to switching the receiver 105 from the HP RX mode to the LP RX mode, the PLL 137 is controlled to operate in the second high bandwidth mode for the period of time HBWTP and is then switched back to operate in the first low bandwidth mode. By operating the PLL 137 in a similar fashion as in the transmitter 117, the PLL 137 is able to achieve fast resettling in the receiver 105. In addition, although the above examples pertain to switching a transmitter from a HP TX mode to a LP TX mode, the PLL 137 may be controlled to operate according to the novel technique when the transmitter switches from the LP TX mode to the HP TX mode, or similarly when the receiver switches from the LP RX mode to the HP RX mode. Accordingly, various modifications, adaptations, and combinations of the various features of the described specific embodiments can be practiced without departing from the scope of the claims that are set forth below.

What is claimed is:

1. A Phase-Locked Loop (PLL) circuit comprising:
a Voltage Controlled Oscillator (VCO) that outputs a VCO output signal; and
a mode control circuit that receives a transmitter power mode control signal (TX HP/LP), wherein TX HP/LP has a transition indicative of a transmitter switching from a High Power (HP TX) mode to a Low Power (LP TX) mode, wherein the mode control circuit in response to the transition: 1) causes the PLL to switch from operating in a first low bandwidth mode to operating in a second high bandwidth mode and then to operate in the second high bandwidth mode for a high bandwidth time period (HBWTP), and 2) at an ending of HBWTP causes the PLL to switch from operating in the second high bandwidth mode to operating in the first low bandwidth mode.

2. The PLL circuit of claim 1, wherein the mode control circuit receives the transmitter power mode control signal TX HP/LP when the VCO output signal has a frequency F_{VCO}_{_{—}}_{BEG}, wherein at the ending of HBWTP a frequency F_{VCO}_{_{—}}_{END} of the VCO output signal is substantially identical to F_{VCO}_{_{—}}_{BEG}, and wherein within twenty-five microseconds of the transition the frequency of the VCO output signal is substantially identical to F_{VCO}_{_{—}}_{BEG}.

3. The PLL circuit of claim 2, wherein at the ending of HBWTP the frequency F_{VCO}_{_{—}}_{END} of the VCO output signal is within one part-per-million (ppm) of F_{VCO}_{_{—}}_{BEG}.

4. The PLL circuit of claim 1, further comprising:
a first charge pump;
a first loop filter, wherein when the PLL operates in the first low bandwidth mode the first charge pump and the first loop filter are parts of a first control loop, wherein the first control loop supplies a first tuning signal onto a first tuning control input lead of the VCO, and wherein the first control loop has a first bandwidth BW1;
a second charge pump; and
a second loop filter, wherein when the PLL operates in the second high bandwidth mode the second charge pump and the second loop filter are parts of a second control loop, wherein the second control loop supplies a second tuning signal onto a second tuning control input lead of the VCO, wherein the second control loop has a second bandwidth BW2, and wherein BW2 is at least twice BW1.

5. The PLL circuit of claim 4, further comprising:
a single Phase-Frequency Detector (PFD) having a first output lead and a second output lead, wherein an up charge pump control signal (UP) present on the first output lead and a down charge pump control signal (DN) present on the second output lead are supplied to the first charge pump if the PLL is operating in the first low bandwidth mode, and wherein the signals UP and DN are supplied to the second charge pump if the PLL is operating in the second high bandwidth mode.

6. The PLL circuit of claim 4, further comprising:
a voltage clamp circuit, wherein a lead of the voltage clamp circuit is coupled to the second tuning control input lead of the VCO thereby causing the second tuning voltage present on the second tuning control input lead of the VCO to float to a pre-determined Direct Current (DC) mid-range voltage (VMID) when the PLL operates in the first low bandwidth mode.

7. The PLL circuit of claim 4, wherein the second bandwidth BW2 is at least ten times the first bandwidth BW1.

8. The PLL circuit of claim 4, wherein the first loop filter has a first filter response, wherein the second loop filter has a second filter response, and wherein both the first and second filter responses are substantially constant throughout a twenty-five microsecond period starting at the transition of TX HP/LP.

9. The PLL circuit of claim 8, wherein a peak output current of current pulses output by the first charge pump does not change during the twenty-five microsecond period, and wherein a peak output current of current pulses output by the second charge pump does not change during the twenty-five microsecond period.

10. The PLL circuit of claim 1, wherein the PLL receives a reference clock signal (PREF), and wherein the mode control circuit causes the PLL to switch from operating in the first low bandwidth mode to operating in the second high bandwidth mode substantially synchronously with a falling edge of FREF.

11. The PLL circuit of claim 1, wherein the VCO includes a mode control input lead, wherein the VCO operates in a high current consumption mode (VCOHP) if a digital control signal on the mode control input lead has a first digital logic level, and wherein the VCO operates in a low current consumption mode (VCOLP) if the digital control signal on the mode control input lead has a second digital logic level.

12. The PLL circuit of claim 1, wherein the VCO is operable in a high current consumption mode (VCOHP) and in a low current consumption mode (VCOLP), wherein the VCO is switched from operating in the high current consumption mode VCOHP to the low current consumption mode VCOLP in response to the transmitter switching from the HP TX mode to the LP TX mode.

13. The PLL circuit of claim 1, wherein the PLL circuit is part of the transmitter, and wherein the transmitter engages in a Wideband Code Division Multiple Access (W-CDMA) communication.

14. A method of operating a Phase-Locked Loop (PLL) of a local oscillator, comprising:
(a) operating the PLL in a low bandwidth mode, wherein a Voltage Controlled Oscillator (VCO) of the PLL outputs a VCO output signal (VO);
(b) while the PLL is operating in the low bandwidth mode supplying a local oscillator signal (LO) to a transmit chain of a transmitter while the transmitter is operating in a High Power (HP TX) mode, wherein the local oscillator generates LO using VO, and wherein the local oscillator and the transmit chain are parts of the transmitter;
(c) switching the transmitter from operating in the HP TX mode to operating in a Low Power (LP TX) mode, wherein VO had a frequency F_{VCO}_{_{—}}_{BEGIN} immediately prior to the switching of step (c);
(d) in response to the switching of step (c), switching the PLL from operating in the low bandwidth mode to operating in a high bandwidth mode;
(e) operating the PLL in the high bandwidth mode for a high bandwidth time period (HBWTP); and
(f) switching the PLL from operating in the high bandwidth mode to operating in the low bandwidth mode, wherein the VCO output signal VO has settled to a frequency F_{VCO} within twenty-five microseconds of the switching of step (c), and wherein the frequency F_{VCO} is within one ppm of the frequency F_{VCO}_{_{—}}_{BEGIN}.

15. The method of claim 14, wherein the PLL has a first control loop and a second control loop, wherein the operating of the PLL in the low bandwidth mode in step (a) involves using the first control loop, and wherein the operating of the PLL in the high bandwidth mode in step (e) involves using the second control loop.

16. The method of claim 15, wherein the first control loop has a first bandwidth BW1, wherein the second control loop has a second bandwidth BW2, and wherein BW2 is at least twice BW1.

17. The method of claim 15, wherein the first control loop has a first bandwidth BW1, wherein the second control loop has a second bandwidth BW2, and wherein the second bandwidth BW2 is at least ten times the first bandwidth BW1.

18. The method of claim 14, wherein the operating in step (a) of the PLL in the low bandwidth mode involves using a first control loop to supply a first tuning voltage onto a first tuning control input lead of the VCO, and wherein the operating in step (e) of the PLL in the high bandwidth mode involves using a second control loop to supply a second tuning voltage onto a second tuning control input lead of the VCO.

19. The method of claim 18, wherein the PLL includes a voltage clamp circuit, wherein a lead of the voltage clamp circuit is coupled to the second tuning control input lead of the VCO thereby causing the second tuning voltage present on the second tuning control input lead of the VCO to be set to a pre-determined Direct Current (DC) mid-range voltage VMID when the PLL operates in the low bandwidth mode.

20. The method of claim 14, wherein at an ending of the period of time HBWTP the VCO output signal VO has a frequency F_{VCO}_{_{—}}_{END} that is within one part-per-million (ppm) of the frequency F_{VCO}_{_{—}}_{BEGIN}.

21. The method of claim 14, wherein the PLL uses a first charge pump and a first loop filter when the PLL operates in the low bandwidth mode, wherein the first charge pump and the first loop filter are parts of a first control loop that supplies a first tuning voltage onto a first tuning control input lead of the VCO, wherein the PLL uses a second charge pump and a second loop filter when the PLL operates in the high bandwidth mode, and wherein the second charge pump and the second loop filter are parts of a second control loop that supplies a second tuning voltage onto a second tuning control input lead of the VCO.

22. The method of claim 21, wherein the PLL includes one and only one Phase-Frequency Detector (PFD), wherein the PFD generates an up charge pump control signal UP and a down charge pump control signal DN, wherein the signals UP and DN are supplied to the first charge pump when the PLL is operating in the low bandwidth mode, and wherein the signals UP and DN are supplied to the second charge pump when the PLL is operating in the high bandwidth mode.

23. The method of claim 14, wherein the transmit chain of the transmitter includes a mixer, and wherein local oscillator signal LO is received onto the mixer in step (b).

24. The method of claim 14, wherein the PLL receives a reference clock signal (FREF), and wherein the switching of the PLL to operate in the high bandwidth mode in step (d) occurs at a beginning of the period of time HBWTP that is substantially synchronous with a falling edge of FREF.

25. The method of claim 14, further comprising:
(d2) switching the VCO from operating in a high current consumption mode (VCOHP) to operating in a low current consumption mode (VCOLP), wherein the switching of step (d2) occurs in response to the switching of step (c) and occurs prior to the switching of (f).

26. The method of claim 14, wherein the steps of (a)-(f) are performed while the PLL is used to engage in a Wideband Code Division Multiple Access (W-CDMA) communication.

27. A Phase-Locked Loop (PLL) circuit comprising:
a Voltage Controlled Oscillator (VCO) having a first tuning control input lead and a second tuning control input lead;
a first charge pump;
a first loop filter, wherein the PLL is operable in a first low bandwidth mode using the first charge pump and the first loop filter as parts of a first control loop, wherein the first control loop supplies a first tuning signal onto the first tuning control input lead of the VCO, wherein the VCO generates an output signal (VO) having a frequency F_{VCO}_{_{—}}_{BEG}, and wherein the first control loop has a first bandwidth BW1; and
means for operating the PLL in a second high bandwidth mode for a predetermined and controlled period of time (HBWTP), wherein the means is part of a second control loop, wherein the second control loop supplies a second tuning signal onto the second tuning control input lead of the VCO, wherein the VCO at an ending of HBWTP generates VO having a frequency F_{VCO}_{_{—}}_{END}, wherein F_{VCO}_{_{—}}_{END} is substantially identical to F_{VCO}_{_{—}}_{BEG}.

28. The PLL of claim 27, wherein the second control loop has a second bandwidth BW2, and wherein BW2 is at least twice BW1

29. The PLL circuit of claim 27, wherein the means comprises a second charge pump and a second loop filter, and wherein the PLL circuit further comprises:
mode control circuit that receives a transmitter power mode control signal (TX HP/LP), wherein TX HP/LP has a transition indicative of a transmitter switching from a High Power (HP TX) mode to a Low Power (LP TX) mode, wherein the mode control circuit in response to the transition: 1) causes the PLL to switch from operating in the first low bandwidth mode to operating in the second high bandwidth mode and then to operate in the second high bandwidth mode for HBWTP, and 2) at an ending of HBWTP causes the PLL to switch from operating in the second high bandwidth mode to operating in the first low bandwidth mode.

30. The PLL circuit of claim 29, wherein the PLL receives a reference clock signal (FREF), and wherein the mode control circuit causes the PLL to operate in the second high bandwidth mode for the period of time HBWTP such that a beginning of the period of time HBWTP is substantially synchronous with a falling edge of FREF.

31. The PLL circuit of claim 27, wherein the PLL circuit is part of a W-CDMA transmitter.
